(19) United States
(12) Patent Application Publication
(10) Pub. No.: US 2026/0293508 A1
(43) Pub. Date: Sep. 24, 2026

(54) DISPLAY MODULE AND ELECTRONIC APPARATUS INCLUDING THE SAME

(71) Applicant: Samsung Display Co., Ltd., Yongin-si (KR)

(72) Inventors: Soohong Cheon, Yongin-si (KR); Donghyun Kim, Yongin-si (KR); Chulkyu Kang, Yongin-si (KR); Seoni Jeong, Yongin-si (KR)

(21) Appl. No.: 19/570,631

(22) Filed: Mar. 18, 2026

(30) Foreign Application Priority Data
Mar. 20, 2025 (KR) 10-2025-0036218
Jul. 2, 2025 (KR) 10-2025-0088887

(51) Int. Cl. H10K 59/88; H10K 59/121; H10K 59/131

(52) U.S. Cl. CPC H10K 59/88; H10K 59/1213; H10K 59/1315

(57) ABSTRACT

A display module includes a light-emitting diode in a display area, a pixel circuit in the display area and electrically connected to the light-emitting diode, where the pixel circuit includes a switching transistor that includes a switching semiconductor layer and a switching gate electrode, a gate driver in a non-display area adjacent to the display area and electrically connected to the switching transistor of the pixel circuit, a dummy transistor in the non-display area and including a dummy semiconductor layer and a dummy gate electrode overlapping a portion of the dummy semiconductor layer, a dummy driver in the non-display area and electrically connected to the dummy gate electrode of the dummy transistor, and a voltage line on the dummy transistor in the non-display area and electrically connected to the dummy semiconductor layer of the dummy transistor.

This application claims priority to Korean Patent Application No. 10-2025-0036218, filed on Mar. 20, 2025, and Korean Patent Application No. 10-2025-0088887, filed on Jul. 2, 2025, and all the benefits accruing therefrom under 35 U.S.C. §119, the contents of which in their entireties are herein incorporated by reference.

### BACKGROUND

### 1. Field

Embodiments of the present disclosure relate to a display module and an electronic apparatus including the display module, and more particularly, to a display module capable of displaying high-quality images and an electronic apparatus including the display module.

### 2. Description of the Related Art

A display module is used in various electronic apparatuses. Such a display module typically includes a pixel array and drivers for driving the pixels. As demand for displaying high-quality images increases, it may be desired to monitor drivers with enhanced precision and accuracy.

### SUMMARY

One or more embodiments include a display module capable of monitoring drivers and an electronic apparatus including the same to display high-quality images. However, such embodiments are examples, and the scope of the present disclosure is not limited thereto.

Additional embodiments will be set forth in part in the description which follows and, in part, will be apparent from the description, or may be learned by practice of the presented embodiments of the disclosure.

According to one or more embodiments, a display module includes: a light-emitting diode disposed in a display area; a pixel circuit disposed in the display area and electrically connected to the light-emitting diode, where the pixel circuit includes a driving transistor and a switching transistor, the driving transistor includes a driving semiconductor layer and a driving gate electrode, and the switching transistor includes a switching semiconductor layer and a switching gate electrode; a gate driver disposed in a non-display area adjacent to the display area and electrically connected to the switching transistor of the pixel circuit; a dummy transistor disposed in the non-display area and including a dummy semiconductor layer and a dummy gate electrode overlapping a portion of the dummy semiconductor layer in a plan view; a dummy driver disposed in the non-display area and electrically connected to the dummy gate electrode of the dummy transistor; and a voltage line disposed on the dummy transistor in the non-display area and electrically connected to the dummy semiconductor layer of the dummy transistor.

In an embodiment, the switching semiconductor layer and the dummy semiconductor layer may include a same material.

In an embodiment, each of the switching semiconductor layer and the dummy semiconductor layer may include an oxide semiconductor.

In an embodiment, a material of the dummy gate electrode may be the same as a material of the switching gate electrode.

In an embodiment, a voltage transmitted through the voltage line may have a constant voltage level.

In an embodiment, the dummy semiconductor layer of the dummy transistor may include a high resistance region, and a first low resistance region and a second low resistance region respectively disposed on two opposite sides of the high resistance region, the dummy gate electrode of the dummy transistor may overlap the high resistance region in the plan view, and an entire portion of each of the high resistance region, the first low resistance region, and the second low resistance region of the dummy semiconductor layer may overlap the voltage line in the plan view.

In an embodiment, the display module may further include a dummy gate line extending in a same direction as the voltage line in the non-display area and electrically connected to the dummy driver, where the dummy gate electrode may be integrally connected to the dummy gate line as a single unitary indivisible part.

According to one or more embodiments, a display module includes: a gate line extending in a first direction in a display area; a pixel circuit disposed in the display area and including a switching transistor and a driving transistor, where the switching transistor is electrically connected to the gate line, and the driving transistor is electrically connected to the switching transistor; a light-emitting diode electrically connected to the pixel circuit and disposed in the display area; a gate driver disposed in a non-display area adjacent to the display area and electrically connected to the gate line; a dummy driver disposed in the non-display area; a dummy gate line disposed in the non-display area and electrically connected to the dummy driver; a dummy transistor disposed in the non-display area and including a dummy semiconductor layer and a dummy gate electrode, where the dummy gate electrode overlaps a portion of the dummy semiconductor layer in a plan view and is electrically connected to the dummy gate line; and a voltage line disposed on the dummy transistor in the non-display area and electrically connected to the dummy semiconductor layer of the dummy transistor.

In an embodiment, the dummy semiconductor layer may include a same material as a material of a switching semiconductor layer of the switching transistor.

In an embodiment, a material of the dummy gate electrode may be the same as a material of a gate electrode of the switching transistor.

In an embodiment, a voltage transmitted through the voltage line may have a constant voltage level.

In an embodiment, the dummy semiconductor layer of the dummy transistor may include a high resistance region, and a first low resistance region and a second low resistance region respectively disposed on two opposite sides of the high resistance region, the dummy gate electrode of the dummy transistor may overlap the high resistance region in the plan view, and an entire portion of the dummy semiconductor layer may overlap the voltage line in the plan view.

In an embodiment, the dummy gate line may be integrally connected to the dummy gate electrode as a single unitary indivisible part.

According to one or more embodiments, an electronic apparatus includes: a display module; and a power module which supplies power to the display module, where the display module includes: a light-emitting diode disposed in a display area; a pixel circuit disposed in the display area and electrically connected to the light-emitting diode, where the pixel circuit includes a driving transistor and a switching transistor, the driving transistor includes a driving semiconductor layer and a driving gate electrode, and the switching transistor includes a switching semiconductor layer and a switching gate electrode; a gate driver disposed in a non-display area adjacent to the display area and electrically connected to the switching transistor of the pixel circuit; a dummy transistor disposed in the non-display area and including a dummy semiconductor layer and a dummy gate electrode overlapping a portion of the dummy semiconductor layer in a plan view; a dummy driver disposed in the non-display area and electrically connected to the dummy gate electrode of the dummy transistor; and a voltage line disposed on the dummy transistor in the non-display area and electrically connected to the dummy semiconductor layer of the dummy transistor.

In an embodiment, the switching semiconductor layer and the dummy semiconductor layer may include a same material.

In an embodiment, each of the switching semiconductor layer and the dummy semiconductor layer may include an oxide semiconductor.

In an embodiment, a material of the dummy gate electrode may be the same as a material of the switching gate electrode.

In an embodiment, a voltage transmitted through the voltage line may have a constant voltage level.

In an embodiment, the dummy semiconductor layer of the dummy transistor may include a high resistance region, and a first low resistance region and a second low resistance region respectively disposed on two opposite sides of the high resistance region, the dummy gate electrode of the dummy transistor may overlap the high resistance region in the plan view, and an entire portion of each of the high resistance region, the first low resistance region, and the second low resistance region of the dummy semiconductor layer may overlap the voltage line in the plan view.

In an embodiment, the display module may further include a dummy gate line extending in a same direction as the voltage line in the non-display area and electrically connected to the dummy driver, where the dummy gate electrode may be integrally connected to the dummy gate line as a single unitary indivisible part.

### BRIEF DESCRIPTION OF THE DRAWINGS

The above and other features of certain embodiments of the disclosure will be more apparent from the following description taken in conjunction with the accompanying drawings, in which:

FIG. 1A is a block diagram of an electronic apparatus according to an embodiment;

FIG. 1B is a schematic view of electronic apparatuses according to various embodiments;

FIG. 2 is a schematic plan view of a display module according to an embodiment;

FIG. 3 is a schematic equivalent circuit diagram of a light-emitting diode corresponding to a pixel of a display module and a pixel circuit, according to an embodiment;

FIG. 4 is a cross-sectional view of a portion of a display area of a display module according to an embodiment;

FIG. 5 is a schematic plan view of a display module according to an embodiment;

FIG. 6 is an enlarged plan view of a region VI of FIG. 5;

FIG. 7 is a plan view of a portion of a dummy element region according to an embodiment;

FIG. 8 is a cross-sectional view taken along line VIII-VIII' of FIG. 7; and

FIG. 9 is a cross-sectional view taken along line IX-IX' of FIG. 7.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

Hereinafter, embodiments of the present disclosure will be described with reference to the accompanying drawings, in which like or corresponding elements are given like reference numerals when describing with reference to the drawings, and any repetitive detailed description thereof will be omitted or simplified.

It will be understood that when an element is referred to as being “on” another element, it can be directly on the other element or intervening elements may be present therebetween. In contrast, when an element is referred to as being “directly on” another element, there are no intervening elements present. In addition, for convenience of description, in the drawings, the sizes of elements may be exaggerated or reduced. As an example, the size and thickness of each element shown in the drawings are arbitrarily represented for convenience of description, and thus, the disclosure is not necessarily limited thereto.

In an embodiment below, an x axis, a y axis and a z axis are not limited to three axes of the rectangular coordinate system, and may be interpreted in a broader sense including the same. For example, the x axis, y axis, and z axis may be perpendicular to one another, or may represent different directions that are not perpendicular to one another.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the present specification, "A and/or B" means A or B, or A and B. In addition, "at least one of A and B" or "at least one selected from A and B" means A or B, or A and B.

In embodiments below, when a layer, region, or element is referred to as being connected, it includes not only a case where the layer, region, or element is directly connected, but also a case where the layer, region, or element is indirectly connected with another layer, region, or element disposed therebetween. For example, in the present specification, when a layer, region, or element is referred to as being electrically connected, it represents a case where the layer, region, or element is directly electrically connected and/or a case where the layer, region, or element is indirectly electrically connected with another layer, region, or element disposed therebetween.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

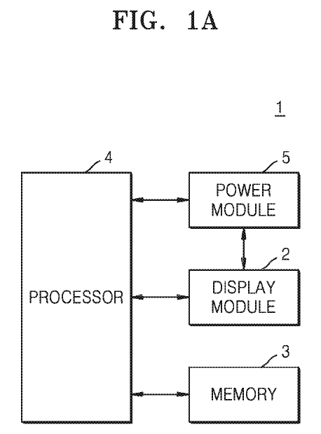

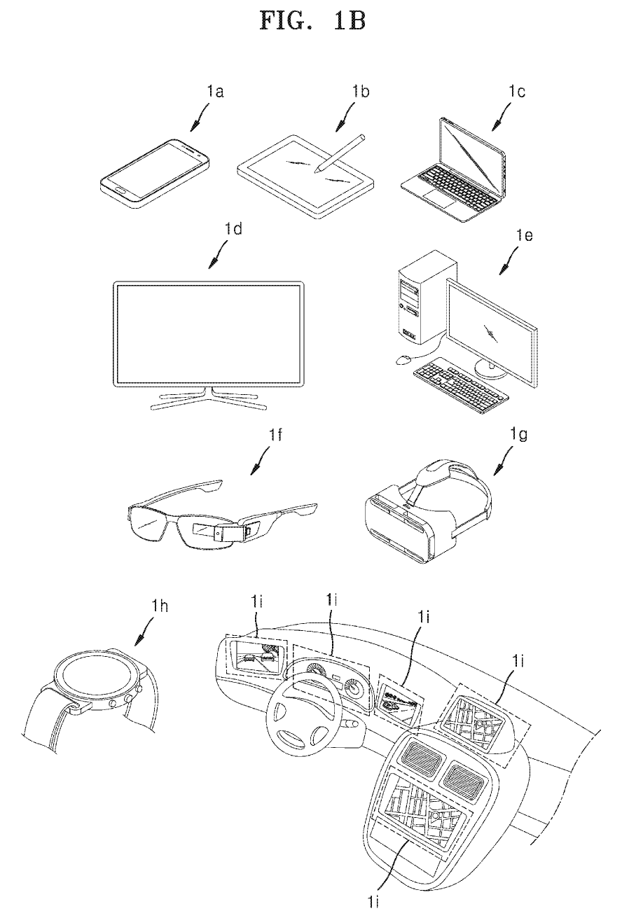

FIG. 1A is a block diagram of an electronic apparatus 1 according to an embodiment. FIG. 1B is a schematic view of electronic apparatuses according to various embodiments.

Referring to FIG. 1A, the electronic apparatus 1 according to an embodiment may include a display module 2, a memory 3, a processor 4, and a power module 5. In an embodiment, the display module 2 may include a display panel (not shown), a gate driver circuitry (not shown), and a data driver circuitry (not shown). In an embodiment, the gate driver circuitry (not shown), and/or the data driver circuitry (not shown) may be formed together during a process of forming the display panel. In this case, the display panel may be the display module 2.

The processor 4 may include at least one selected from a central processing unit (CPU), an application processor (AP), a graphic processing unit (GPU), a communication processor (CP), an image signal processor (ISP), and a controller.

The memory 3 may store data information used for operations of the processor 4 or the display module 2. When the processor 4 executes an application stored in the memory 3, image data signals and/or input control signals may be transferred to the display module 2, and the display module 2 may process provided signals and output image information through a display screen.

The power module 5 may include a power supply module such as a power adapter or a battery unit, and a power converting module converting power supplied by the power supply module and generating power used for operations of the electronic apparatus 1.

At least one of elements of the electronic apparatus 1 may be included in a display device including the display module 2. In addition, some of individual modules functionally included in one module may be included in the display device, and others may be provided separately from the display device. In an embodiment, for example, the display device may include the display module 2, and the processor 4, the memory 3, and the power module 5 may be provided in the form of another device within the electronic apparatus 1 instead of the display device.

Referring to FIG. 1B, the electronic apparatuses according to embodiments may include not only electronic apparatuses for displaying images such as a smartphone 1a, a tablet personal computer (PC) 1b, a laptop computer 1c, a television (TV) 1d, and a desk monitor 1e, but also wearable electronic apparatuses including a display module such as a smart glasses 1f, a head mount display 1g, and a smartwatch 1h, and vehicle electronic apparatuses 1i including a display module such as an instrument panel of an automobile, a center facia, a center information display (CID) disposed on a dashboard, and a room mirror display.

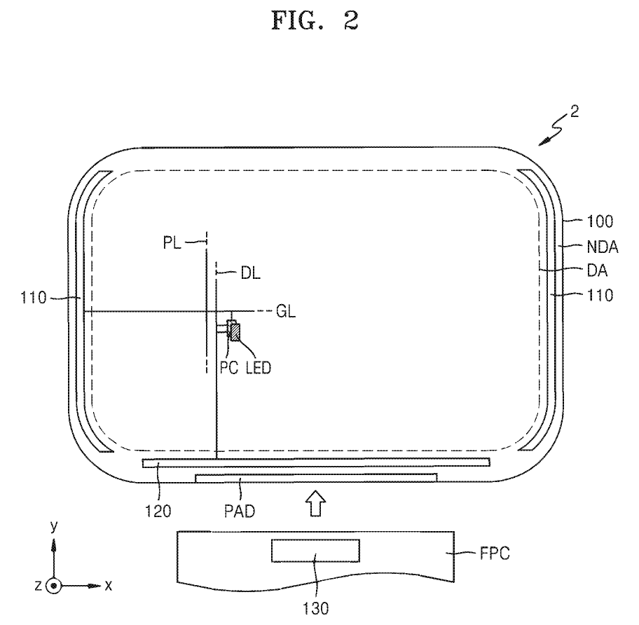

FIG. 2 is a schematic plan view of the display module 2 according to an embodiment.

Referring to FIG. 2, an embodiment of the display module 2 may include a display area DA and a non-display area NDA outside the display area DA. Elements of the display module 2 positioned in the display area DA and the non-display area NDA may be disposed on the substrate 100. The elements of the display module 2 may be disposed on the substrate 100 or physically or electrically connected to a partial region of the substrate 100. In an embodiment where the display module 2 includes the display area DA and the non-display area NDA, it may be understood that elements therein, e.g., the substrate 100, also includes the display area DA and the non-display area NDA.

Pixels may be disposed in the display area DA, and the display area DA may display images by using light emitted from the pixels. Each pixel may include a light-emitting diode LED, and the light-emitting diode LED may be electrically connected to a pixel circuit PC. The light-emitting diode LED and the pixel circuit PC may be disposed in the display area DA of the substrate 100, and the light-emitting diode LED on the pixel circuit PC may overlap the pixel circuit PC. The pixel circuit PC may be electrically connected to a gate line GL, a data line DL, a driving voltage line PL, and the like. The gate line GL may extend in a first direction (e.g., an x direction) in the display area DA, and the data line DL and the driving voltage line PL may extend in a second direction (e.g., a y direction) crossing the first direction.

A gate driver circuitry 110, a data driver circuitry 120, and a pad PAD may be disposed in the non-display area NDA. The gate driver circuitry 110 may be disposed on two opposite sides (e.g., the left and the right) of the display area DA in a plan view, i.e., when viewed in a third direction (a z direction), and the data driver circuitry 120 may be disposed on one side (e.g., the lower side) of the display area DA in a plan view. The data driver circuitry 120 may be disposed between the display area DA and the pad PAD in a plan view. Here, the third direction or the z direction may be a thickness direction of the substrate 100.

The gate driver circuitry 110 may generate a gate signal in response to a gate driving control signal input from a controller 130 and provide the generated gate signal to the gate lines GL. Some of the pixel circuits PC disposed in the display area DA may be electrically connected to the gate driver circuitry 110 on the left, and the others may be connected to the gate driver circuitry 110 on the right. The gate driver circuitry 110 may provide gate signals to the pixel circuit PC through the gate line GL. FIG. 2 shows an embodiment with two gate driver circuitries 110. However, the present disclosure is not limited thereto. In an embodiment, one of the two gate driver circuitries 110 may be omitted. In an embodiment, three or more gate driver circuitries 110 may be disposed.

The data driver circuitry 120 may convert an image signal into a data signal in the form of a voltage or a current according to a data driving control signal input from the controller 130.

The controller 130 may generate a data driving control signal and a gate driving control signal in response to synchronization signals supplied from the outside. The controller 130 may output a gate driving control signal to the gate driver circuitry 110, and output a data driving control signal to the data driver circuitry 120.

The pad PAD may be exposed by not being covered by an insulating layer, and may be electrically connected to a display circuit board FPC. A pad (not shown) of the display circuit board FPC may be electrically connected to the pad PAD provided on the substrate 100.

The display circuit board FPC transfers a signal of the controller 130 or power to a driver circuitry and a power line on the substrate 100. Signals generated by the controller 130 may be respectively transferred to the gate driver circuitry 110 and the data driver circuitry 120 through the display circuit board FPC.

Although FIG. 2 shows an embodiment where the data driver circuitry 120 is disposed on the substrate 100, the present disclosure is not limited thereto. In another embodiment, the data driver circuitry 120 and the controller 130 may be integrally formed in an integrated circuit (IC) chip and disposed on the display circuit board FPC.

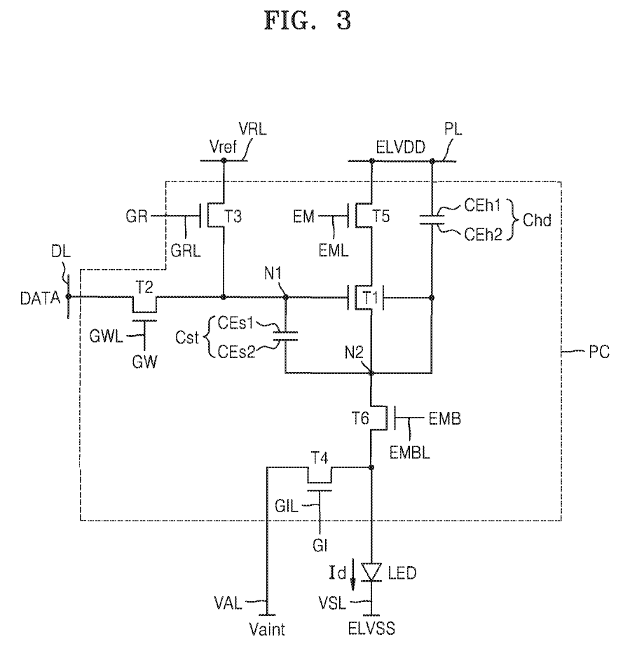

FIG. 3 is a schematic equivalent circuit diagram of the light-emitting diode LED corresponding to the pixel of the display module and the pixel circuit PC according to an embodiment.

Referring to FIG. 3, in an embodiment, the pixel circuit PC may include first to sixth transistors T1 to T6, a storage capacitor Cst, and a hold capacitor Chd, and the pixel circuit PC may be electrically connected to the light-emitting diode LED.

The first transistor T1 may be a driving transistor configured to output a driving current corresponding to a data signal, and the second to sixth transistors T2, T3, T4, T5, and T6 may be switching transistors configured to transfer signals. A first terminal (a first electrode) of each of the first to sixth transistors T1, T2, T3, T4, T5, and T6 may be a source or a drain, and a second terminal (a second electrode) may be a terminal different from the first terminal. For example, in a case where the first terminal is a drain, the second terminal may be a source.

In an embodiment, the first to sixth transistors T1 to T6 may be metal-oxide-semiconductor field-effect transistors (MOSFETs). In such an embodiment, at least one of the first to sixth transistors T1, T2, T3, T4, T5, and T6 may be p-channel MOSFET (PMOSs), and the others may be n-channel MOSFET (NMOSs). In an embodiment, for example, the fifth transistor T5 may be a PMOS, and the first, second, third, fourth, and sixth transistors T1, T2, T3, T4, and T6 may be NMOSs. In another embodiment, the fifth transistor T5 and the sixth transistor T6 may be PMOSs, and the first, second, third, and fourth transistors T1, T2, T3, and T4 may be NMOSs. Alternatively, all of the first to sixth transistors T1, T2, T3, T4, T5, and T6 may be NMOSs or PMOSs. Hereinafter, for convenience of description, embodiments in which the first to sixth transistors T1, T2, T3, T4, T5, and T6 are n-channel MOSFET (NMOS) including an oxide semiconductor will be mainly described.

The pixel circuit PC may be electrically connected to gate lines that transfer signals to a gate (or control terminal) of each of the first to sixth transistors T1, T2, T3, T4, T5, and T6. The gate lines may include a scan line GWL that transfers a scan signal GW, an initialization gate line GIL that transfers an initialization signal GI, a reference gate line GRL that transfers a reference signal GR, a first emission control line EML that transfers a first emission control signal EM, and a second emission control line EMBL that transfers a second emission control signal EMB. The pixel circuit PC may be connected to the data line DL that transfers a data signal DATA, the driving voltage line PL that transfers a driving voltage ELVDD, a reference voltage line VRL that transfers a reference voltage Vref, and an initialization voltage line VAL that transfers an initialization voltage Vaint.

A node to which a first gate of the first transistor T1 is connected may be defined as a first node N1, and a node to which a second terminal of the first transistor T1 is connected may be defined as a second node N2.

The first transistor T1 may be connected between the driving voltage line PL and the light-emitting diode LED. The first transistor T1 may be electrically connected between the fifth transistor T5 and the sixth transistor T6. The first transistor T1 may include a gate, a first terminal, and a second terminal connected to the second node N2. The first terminal may be a drain D, and the second terminal may be a source S. The gate of the first transistor T1 may include a first gate connected to the first node N1, and a second gate connected to the second node N2. The first gate and the second gate may be disposed in different layers to face each other. In an embodiment, for example, the first gate and the second gate of the first transistor T1 may be positioned to face each other with a semiconductor layer therebetween. Hereinafter, a gate (a gate electrode) of the first transistor T1 may denote a first gate involved in turning on and off of the first transistor T1.

The first terminal of the first transistor T1 may be connected to the driving voltage line PL through the fifth transistor T5, and the second terminal may be connected to a pixel electrode of the light-emitting diode LED. The first transistor T1 may receive a data signal DATA based on a switching operation of the second transistor T2 and be configured to control the amount of driving current flowing through the light-emitting diode LED. Accordingly, the first transistor T1 may be referred to as a driving transistor.

The second transistor T2 may be connected between the data line DL and the first node N1. The second transistor T2 may include a gate, a first terminal, and a second terminal, where the gate is connected to the scan line GWL, the first terminal is connected to the data line DL, and the second terminal is connected to the first node N1. The second transistor T2 may be turned on by a scan signal GW transferred to the scan line GWL to electrically connect the data line DL and the first node N1 to each other, and may transfer a data signal DATA transferred to the data line DL to the first node N1. Accordingly, the second transistor T2 may be also referred to as a data-write transistor.

The third transistor T3 may be electrically connected between the first node N1 and the reference voltage line VRL. The third transistor T3 may include a gate, a first terminal, and a second terminal, where the gate is connected to the reference gate line GRL, the first terminal is connected to the first node N1, and the second terminal is connected to the reference voltage line VRL. The third transistor T3 may be turned on according to a reference signal GR transferred to the reference gate line GRL, and may transfer the reference voltage Vref to the first node N1, where the reference voltage Vref is transferred to the reference voltage line VRL. The third transistor T3 may be referred to as a first initialization transistor.

The fourth transistor T4 may be electrically connected between the first transistor T1 and the initialization voltage line VAL. The fourth transistor T4 may include a gate, a first terminal, and a second terminal, where the gate is connected to the initialization gate line GIL, the first terminal is connected to the sixth transistor T6 and the light-emitting diode LED, and the second terminal is connected to the initialization voltage line VAL. The fourth transistor T4 may be turned on in response to an initialization signal GI transferred to the initialization gate line GIL, and may transfer the initialization voltage Vaint to the pixel electrode of the light-emitting diode LED, where the initialization voltage Vaint is transferred to the initialization voltage line VAL. Accordingly, the fourth transistor T4 may be referred to as a second initialization transistor.

The fifth transistor T5 may be electrically connected between the driving voltage line PL and the first transistor T1. The fifth transistor T5 may include a gate, a first terminal, and a second terminal, where the gate is connected to the first emission control line EML, the first terminal is connected to the driving voltage line PL, and the second terminal is connected to the first terminal of the first transistor T1. The fifth transistor T5 may be turned on or turned off in response to a first emission control signal EM transferred to the first emission control line EML. The fifth transistor T5 may be referred to as a driving control transistor.

The sixth transistor T6 may be connected between the first transistor T1 and the light-emitting diode LED. The sixth transistor T6 may include a gate, a first terminal, and a second terminal, where the gate is connected to the second emission control line EMBL, the first terminal is connected to the second node N2, and the second terminal is connected to the light-emitting diode LED. The sixth transistor T6 may be turned on according to a second emission control signal EMB transferred to the second emission control line EMBL and may connect the second node N2 and the pixel electrode of the light-emitting diode LED to each other. The sixth transistor T6 may be also referred to as an emission control transistor.

Although FIG. 3 shows an embodiment where the fifth transistor T5 and the sixth transistor T6 respectively operate in response to different emission control signals EM and EMB from each other, the present disclosure is not limited thereto. In another embodiment, the fifth transistor T5 and the sixth transistor T6 may operate in response to the same emission control signal.

In an embodiment, a reference signal GR may be substantially synchronized with a scan signal GW of the pixel circuit PC located in a previous row. In an embodiment, an initialization signal GI may be substantially synchronized with the scan signal GW. In another embodiment, an initialization signal GI may be substantially synchronized with a scan signal GW of the pixel circuit PC located in a next row or a reference signal GR.

The storage capacitor Cst may be connected between the first node N1 and the second node N2. In an embodiment, the pixel circuit PC may be a source-follower type circuit in which the storage capacitor Cst is connected between the first node N1 and the second node N2. A first storage electrode CEs1 of the storage capacitor Cst may be connected to the first node N1, and a second storage electrode CEs2 may be connected to the second node N2. The storage capacitor Cst may store a threshold voltage of the first transistor T1 and a voltage corresponding to a data signal DATA.

The hold capacitor Chd may be connected between the driving voltage line PL and the second node N2. A first hold electrode CEh1 of the hold capacitor Chd may be connected to the driving voltage line PL, and a second hold electrode CEh2 may be connected to the second node N2. The hold capacitor Chd may ensure that voltages of the second gate of the first transistor T1 and the second node N2 do not fluctuate and have a constant voltage when a surrounding signal fluctuates.

The light-emitting diode LED may include the pixel electrode connected to the second node N2 and an opposite electrode on the pixel electrode, and the opposite electrode may be electrically connected to a common voltage line VSL that provides a common voltage ELVSS. The opposite electrode may be a common electrode shared over a plurality of light-emitting diodes LED.

Although FIG. 3 shows an embodiment where the pixel circuit PC includes six transistors and two capacitors, the present disclosure is not limited thereto. In another embodiment, the pixel circuit PC may include five transistors and two capacitors. In another embodiment, the pixel circuit PC may include seven transistors and two capacitors.

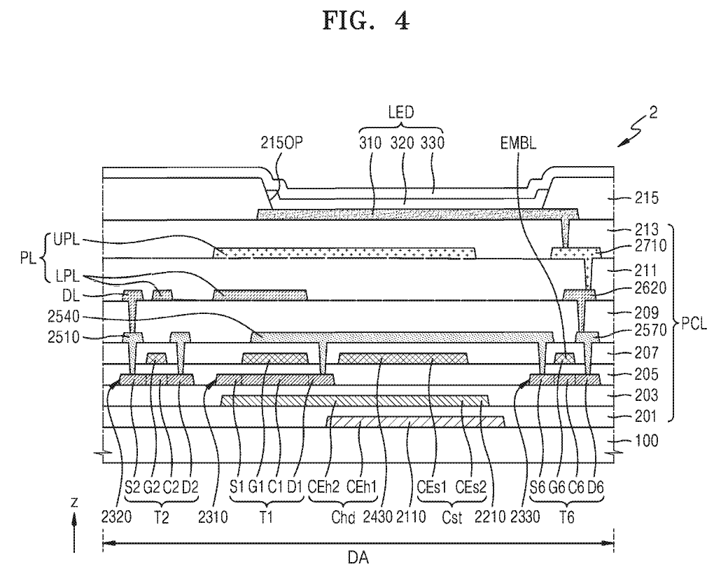

FIG. 4 is a cross-sectional view of a portion the display area DA of the display module 2 according to an embodiment.

Referring to FIG. 4, in an embodiment, the display module 2 may include a circuit layer PCL and a display element layer, where the circuit layer PCL includes transistors and capacitors disposed on the substrate 100, and the display element layer is disposed on the circuit layer PCL and includes the light-emitting diode LED. The circuit layer PCL may include the transistors and the capacitors described above with reference to FIG. 3. The transistors may include the first transistor T1, which is the driving transistor, and the second to sixth transistors T2 to T6, which are switching transistors, as described with reference to FIG. 3, and the capacitors may include the storage capacitor Cst and the hold capacitor Chd as described with reference to FIG. 3. The first transistor T1, which is the driving transistor, may include a driving semiconductor layer and a driving gate electrode, and each of the second to sixth transistors T2 to T6, which are switching transistors, may include a switching semiconductor layer and a switching gate electrode. With regard to this, FIG. 4 shows a cross-section of the first transistor T1, the second transistor T2, the sixth transistor T6, the storage capacitor Cst, and the hold capacitor Chd.

The substrate 100 may include a glass material, a ceramic material, metal, plastic, or a flexible or bendable material. In an embodiment where the substrate 100 is flexible or bendable, the substrate 100 may include a polymer resin including at least one selected from polyethersulfone (PES), polyacrylate, polyether imide (PEI), polyethylene naphthalate (PEN), polyethylene terephthalate (PET), polyphenylene sulfide (PPS), polyarylate, polyimide (PI), polycarbonate, and cellulose acetate propionate (CAP).

The substrate 100 may have a single-layered structure or a multi-layered structure of the above materials, and may further include an inorganic layer in the case of the multi-layered structure. In an embodiment, for example, the substrate 100 may include a stack structure in which a layer including the polymer resin and a barrier layer including an inorganic insulating material are alternately stacked.

A first conductive layer 2110 may be disposed on the substrate 100. The first conductive layer 2110 may include at least one material selected from aluminum (Al), platinum (Pt), palladium (Pd), silver (Ag), magnesium (Mg), gold (Au), nickel (Ni), neodymium (Nd), iridium (Ir), chrome (Cr), lithium(Li), calcium (Ca), molybdenum (Mo), titanium (Ti), tungsten (W), and copper (Cu). In an embodiment, the first conductive layer 2110 may have a molybdenum-single layer, a double-layered structure in which a molybdenum layer and a titanium layer are stacked, or a triple-layered structure in which a titanium layer, an aluminum layer, and a titanium layer are stacked.

A first insulating layer 201 may be disposed on the first conductive layer 2110. The first insulating layer 201 may include an inorganic insulating layer including an inorganic insulating material including at least one selected from silicon nitride, silicon oxide, and/or silicon oxynitride, and has a single layer structure or a multi-layer structure, each layer including at least one selected from the above materials.

A second conductive layer 2210 may be disposed on the first insulating layer 201. The second conductive layer 2210 may include at least one material selected from aluminum (Al), platinum (Pt), palladium (Pd), silver (Ag), magnesium (Mg), gold (Au), nickel (Ni), neodymium (Nd), iridium (Ir), chrome (Cr), lithium(Li), calcium (Ca), molybdenum (Mo), titanium (Ti), tungsten (W), and copper (Cu). In an embodiment, the second conductive layer 2210 may have a molybdenum-single layer, a double-layer structure in which a molybdenum layer and a titanium layer are stacked, or a triple-layer structure in which a titanium layer, an aluminum layer, and a titanium layer are stacked.

The first conductive layer 2110 and the second conductive layer 2210 may overlap each other. Each of the first conductive layer 2110 and the second conductive layer 2210 may include the first hold electrode CEh1 and the second hold electrode CEh2 of the hold capacitor Chd. A portion of the second conductive layer 2210 may overlap the semiconductor layer of the first transistor T1 and correspond to the second gate described with reference to FIG. 3.

A second insulating layer 203 may be disposed on the second conductive layer 2210. The second insulating layer 203 may include an inorganic insulating layer including an inorganic insulating material including at least one selected from silicon nitride, silicon oxide, and/or silicon oxynitride, and has a single layer structure or a multi-layer structure, each layer including at least one selected from the above materials.

A first semiconductor pattern 2310, a second semiconductor pattern 2320, and a third semiconductor pattern 2330 may be disposed on the second insulating layer 203. The first semiconductor pattern 2310, the second semiconductor pattern 2320, and the third semiconductor pattern 2330 may include an oxide semiconductor. The first semiconductor pattern 2310, the second semiconductor pattern 2320, and the third semiconductor pattern 2330 may include, for example, an oxide semiconductor including at least one element selected from indium (In), gallium (Ga), tin (Sn), zirconium (Zr), vanadium (V), hafnium (Hf), cadmium (Cd), germanium (Ge), chrome (Cr), titanium (Ti), aluminum (Al), cesium (Cs), cerium (Ce), and zinc (Zn). In an embodiment, for example, the first semiconductor pattern 2310, the second semiconductor pattern 2320, and the third semiconductor pattern 2330 may include InSnZnO (ITZO) or InGaZnO (IGZO).

Each of the first semiconductor pattern 2310, the second semiconductor pattern 2320, and the third semiconductor pattern 2330 shown in FIG. 4 may include the semiconductor layers of the first transistor T1, the second transistor T2, and the sixth transistor T6, and be apart from each other. Although not shown in FIG. 4, the semiconductor layer (or the switching semiconductor layer) of other switching transistors, for example, the third, fourth, and fifth transistors T3, T4, and T5 (FIG. 3) described with reference to FIG. 3 may be disposed on the second insulating layer 203, and the semiconductor layer (or the switching semiconductor layer) of some transistors may be integrally connected to one of the first to third semiconductor patterns 2310, 2320, and 2330 as a single unitary indivisible part.

The first semiconductor pattern 2310 includes a first semiconductor layer (or the driving semiconductor layer) of the first transistor T1, and the first semiconductor layer may include a first channel region C1, first and second conductive regions S1 and D1, where the first channel region C1 is a high resistance region that overlaps a gate electrode G1 (or the driving gate electrode), and the first and second conductive regions S1 and D1 are low resistance regions disposed on two opposite sides of the first channel region C1. The first and second conductive regions S1 and D1 may be made conductive through a plasma process, metal doping, or the like. The gate electrode G1 of the first transistor T1 may correspond to the first gate described with reference to FIG. 3.

The second semiconductor pattern 2320 includes a second semiconductor layer (or a switching semiconductor layer) of the second transistor T2, and the second semiconductor layer may include a second channel region C2, first and second conductive regions S2 and D2, where the second channel region C2 is a high resistance region that overlaps a gate electrode G2 (or the switching gate electrode), and the first and second conductive regions S2 and D2 are low resistance regions disposed on two opposite sides of the second channel region C2. The first and second conductive regions S2 and D2 may be made conductive through a plasma process, metal doping, or the like.

The third semiconductor pattern 2330 includes a sixth semiconductor layer (or a switching semiconductor layer) of the sixth transistor T6, and the sixth semiconductor layer may include a sixth channel region C6, first and second conductive regions S6 and D6, where the sixth channel region C6 is a high resistance region that overlaps a gate electrode G6 (or the switching gate electrode), and the first and second conductive regions S6 and D6 are low resistance regions disposed on two opposite sides of the sixth channel region C6. In an embodiment, the gate electrode G6 of the sixth transistor T6 may be a portion of the second emission control line EMBL.

A third insulating layer 205 may be disposed between the first semiconductor pattern 2310 and the gate electrode G1 of the first transistor T1, between the second semiconductor pattern 2320 and the gate electrode G2 of the second transistor T2, between the third semiconductor pattern 2330 and the gate electrode G6 of the sixth transistor T6. The third insulating layer 205 may include an inorganic insulating layer including an inorganic insulating material including at least one selected from silicon nitride, silicon oxide, and/or silicon oxynitride, and have a single layer structure or a multi-layer structure, each layer including at least one selected from the above materials.

A third conductive layer 2430 may be disposed on the same layer as the gate electrode G1 of the first transistor T1 and/or the gate electrode G6 of the sixth transistor T6. The third conductive layer 2430 may include at least one material selected from aluminum (Al), platinum (Pt), palladium (Pd), silver (Ag), magnesium (Mg), gold (Au), nickel (Ni), neodymium (Nd), iridium (Ir), chrome (Cr), lithium(Li), calcium (Ca), molybdenum (Mo), titanium (Ti), tungsten (W), and copper (Cu).

The third conductive layer 2430 and the second conductive layer 2210 may overlap each other. Each of the third conductive layer 2430 and the second conductive layer 2210 may include the first storage electrode CEs1 and the second storage electrode CEs2 of the storage capacitor Cst. A portion of the second conductive layer 2210 may have a function of the first storage electrode CEs1 and the second hold electrode CEh2.

A fourth insulating layer 207 may be disposed on the gate electrode G1 of the first transistor T1, the gate electrode G6 of the sixth transistor T6, and the third conductive layer 2430. The fourth insulating layer 207 may include an inorganic insulating layer including an inorganic insulating material including at least one selected from silicon nitride, silicon oxide, and/or silicon oxynitride, and have a single layer structure or a multi-layer structure, each layer including at least one selected from the above materials.

A fourth conductive layer 2540 may electrically connect the first semiconductor layer of the first transistor T1 and the sixth semiconductor layer of the sixth transistor T6 to each other. The fourth conductive layer 2540 may be the second node described with reference to FIG. 3, and although not shown in FIG. 4, the fourth conductive layer 2540 may be electrically connected to the second storage electrode CEs2 and the second hold electrode CEh2.

A data connection electrode 2510 may be disposed on the same layer as the fourth conductive layer 2540. The data connection electrode 2510 may be electrically connected to a first terminal of the second semiconductor layer of the second transistor T2, for example, the first low resistance region S2. The data connection electrode 2510 may include a same material as the fourth conductive layer 2540.

A first connection electrode 2570 may be disposed on the same layer as the fourth conductive layer 2540. The first connection electrode 2570 may be electrically connected to the second semiconductor pattern 2320, for example, a second terminal of the semiconductor layer of the sixth transistor T6. The first connection electrode 2570 may include a same material as the fourth conductive layer 2540.

The fourth conductive layer 2540, the data connection electrode 2510, and the first connection electrode 2570 may include at least one selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). In an embodiment, the fourth conductive layer 2540, the data connection electrode 2510, and the first connection electrode 2570 may have a triple layer structure in which a titanium layer, an aluminum layer, and a titanium layer are stacked.

A fifth insulating layer 209 may be disposed on the fourth conductive layer 2540, the data connection electrode 2510, and the first connection electrode 2570. The fifth insulating layer 209 may include an organic insulating material such as acryl, benzocyclobutene (BCB), polyimide, or hexamethyldisiloxane (HMDSO).

The data line DL may be disposed on the fifth insulating layer 209. The data line DL may be electrically connected to the data connection electrode 2510 through a contact hole defined (or extending) through the fifth insulating layer 209.

The driving voltage line PL may be disposed on the fifth insulating layer 209. In some embodiments, the driving voltage line PL may include a lower driving voltage line LPL and an upper driving voltage line UPL disposed on different layers from each other. A sixth insulating layer 211 may be disposed on the lower driving voltage line LPL and under the upper driving voltage line UPL, and may include an organic insulating material. The lower driving voltage line LPL and under the upper driving voltage line UPL may be electrically connected to each other through a contact hole defined (or extending) through the sixth insulating layer 211.

The data line DL, the lower driving voltage line LPL, and the upper driving voltage line UPL may include at least one selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). In an embodiment, each of the data line DL, the lower driving voltage line LPL, and the upper driving voltage line UPL may have a triple layer structure in which a titanium layer, an aluminum layer, and a titanium layer are stacked.

A second connection electrode 2620 may be disposed on the fifth insulating layer 209 and electrically connected to the first connection electrode 2570. The second connection electrode 2620 may include a same material as the driving voltage line LPL.

A third connection electrode 2710 may be disposed on the sixth insulating layer 211 and electrically connected to the second connection electrode 2620. The second connection electrode 2620 may include a same material as the upper driving voltage line UPL.

Although FIG. 4 shows an embodiment where the driving voltage line PL includes two layers of the lower driving voltage line LPL and the upper driving voltage line UPL, the present disclosure is not limited thereto. In another embodiment, the driving voltage line PL may include one selected from the lower driving voltage line LPL and the upper driving voltage line UPL, and in this case, the sixth insulating layer 211 may be omitted.

A seventh insulating layer 213 may be disposed on the driving voltage line PL. The seventh insulating layer 213 may include an organic insulating material.

The light-emitting diode LED may include a pixel electrode 310, an opposite electrode 330 on the pixel electrode 310, and an intermediate layer 320 between the pixel electrode 310 and the opposite electrode 330.

The pixel electrode 310 may be disposed on the seventh insulating layer 213 and electrically connected to the third connection electrode 2710 through a contact hole defined (or extending) through the seventh insulating layer 213. The pixel electrode 310 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. The pixel electrode 310 may further include a conductive oxide material layer on and/or under the reflective layer. The conductive oxide material layer may include indium tin oxide (ITO), indium zinc oxide (IZO), zinc oxide (ZnO), indium oxide (In₂O₃), indium gallium oxide (IGO), and/or aluminum zinc oxide (AZO). In an embodiment, the pixel electrode 310 may have a three-layer structure of ITO layer/Ag layer/ITO layer.

A bank layer 215 may be disposed on the pixel electrode 310. The bank layer 215 may include or define an opening 215OP that overlaps the pixel electrode 310 and cover the edge of the pixel electrode 310. The bank layer 215 may include an organic insulating material.

The intermediate layer 320 may include the emission layer. In an embodiment, the intermediate layer 320 may further include an emission layer and a functional layer. The functional layer may include a hole transport layer (HTL), a hole injection layer (HIL), an electron transport layer (ETL), and/or an electron injection layer (EIL). In an embodiment, the intermediate layer 320 may include a first stack including the emission layer and the functional layer, a second stack including the emission layer and the functional layer, and a charge generation layer between the first stack and the second stack. The charge generation layer may include a negative charge generation layer and a positive charge generation layer. A light-emission efficiency of a tandem type light-emitting diode LED including the plurality of emission layers, may be enhanced even more by the negative charge generation layer and the positive charge generation layer.

The negative charge generation layer may be an n-type charge generation layer. The negative charge generation layer may supply electrons. The negative charge generation layer may include hosts and dopants. The host may include an organic material. The dopant may include a metal material. The positive charge generation layer may be a p-type charge generation layer. The positive charge generation layer may supply holes. The positive charge generation layer may include hosts and dopants. The host may include an organic material. The dopant may include a metal material.

The opposite electrode 330 may include a conductive material having a low work function. The opposite electrode 330 may include a (semi) transparent layer including silver (Ag), magnesium (Mg), aluminum (Al), platinum (Pt), palladium (Pd), gold (Au), nickel (Ni), neodymium (Nd), and iridium (Ir), chromium (Cr), lithium (Li), calcium (Ca), or an alloy thereof. Alternatively, the opposite electrode 330 may further include a layer on the (semi) transparent layer, the layer including ITO, IZO, ZnO, or In₂O₃.

In an embodiment, an encapsulation layer (not shown) may be disposed on the light-emitting diode LED. The encapsulation layer may include a first inorganic encapsulation layer, a second inorganic encapsulation layer, and an organic encapsulation layer therebetween.

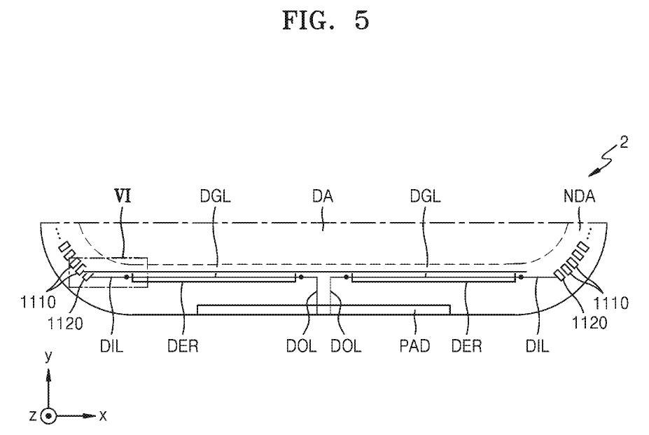

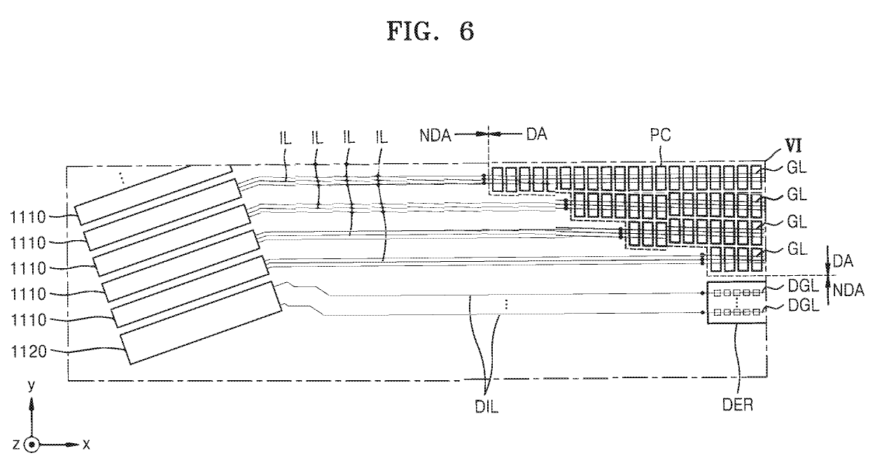

FIG. 5 is a schematic plan view of the display module 2 according to an embodiment, and FIG. 6 is an enlarged plan view of a region VI of FIG. 5.

Referring to FIGS. 2 and 5, in an embodiment, the gate driver circuitries 110 (FIG. 2) may be respectively disposed on the left and right of the display area DA, and each gate driver circuitry 110 (FIG. 2) may include gate drivers 1110 and a dummy driver 1120. In an embodiment, the dummy driver 1120 may be disposed on one side of the gate drivers 1110 arranged in one direction in the non-display area NDA, for example, be disposed adjacent to the gate driver 1110 disposed closest to the pad PAD.

Each gate driver 1110 may include a plurality of stages (not shown), and each stage may output gate signals to the pixel circuits PC disposed in a corresponding row, for example, a scan signal GW, a reference signal GR, an initialization signal GI, a first emission control signal EM, or a second emission control signal EMB. An output gate signal may be transferred to the gate line GL electrically connected to the pixel circuits PC through a connection line IL (FIG. 6). The gate lines GL electrically connected to the pixel circuits PC disposed in one of rows shown in FIG. 6 may include the scan line GWL (FIG. 3), the initialization gate line GIL (FIG. 3), the reference gate line GRL (FIG. 3), the first emission control line EML (FIG. 3), and the second emission control line EMBL (FIG. 3). The connection line IL (FIG. 6) disposed in the non-display area NDA and the gate line GL disposed in the display area DA may be disposed on different layers from each other and be connected to each other in the non-display area NDA. In an embodiment, for example, the connection line IL (FIG. 6) may be disposed on the same layer as one of the first conductive layer 2110 and the second conductive layer 2210 described with reference to FIG. 4, and the gate line GL may be disposed on the same layer as the gate electrode G1 of the first transistor T1.

The dummy driver 1120 may be disposed in the non-display area NDA to monitor a gate signal output from the gate driver 1110 and provided to the gate line GL in the display area DA. The dummy driver 1120 is a type of monitoring driver, may output a dummy gate signal corresponding to a gate signal output from the gate driver 1110, and an output of a gate signal provided to the gate line GL in the display area DA may be monitored by checking an output level of a gate signal provided from the dummy driver 1120.

In an embodiment, for example, a dummy gate signal output from the dummy driver 1120 may be transferred to a dummy gate line DGL passing across a dummy element region (DER) or a dummy element section through a dummy connection line DIL (FIGS. 5 and 6). The dummy gate line DGL (FIGS. 5 and 6) may be electrically connected to a dummy output line DOL (FIG. 6), and an output level of a gate signal provided to the dummy gate line DGL (FIGS. 5 and 6) from the dummy driver 1120 may be monitored by measuring a signal output to the dummy output line DOL. In an embodiment, the dummy connection line DIL and the dummy output line DOL disposed in the non-display area NDA may be disposed in a different layer from the dummy gate line DGL disposed in the display area DA, and be connected to each other in the non-display area NDA. In an embodiment, for example, the dummy connection line DIL and the dummy output line DOL may be disposed in (or directly on) a same layer as one of the first conductive layer 2110 and the second conductive layer 2210 described with reference to FIG. 4, and the dummy gate line DGL may be disposed in (or directly on) a same layer as the gate electrode G1 of the first transistor T1.

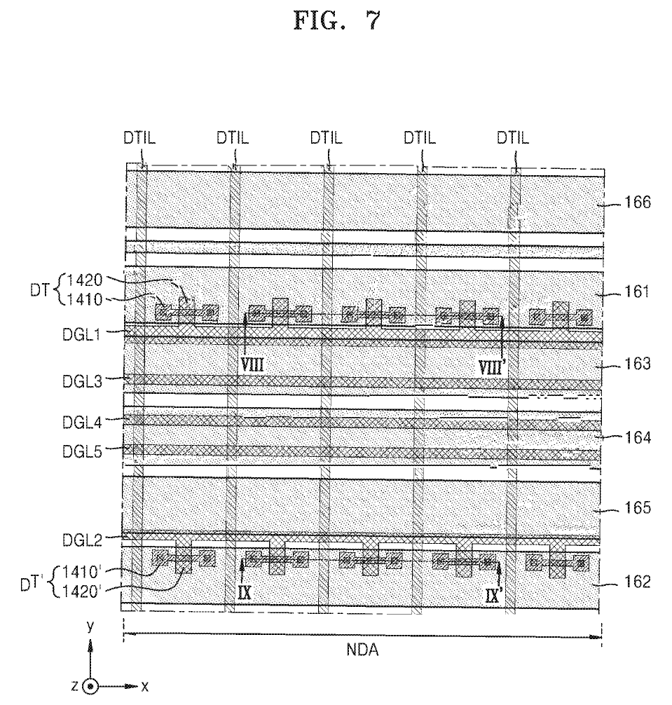

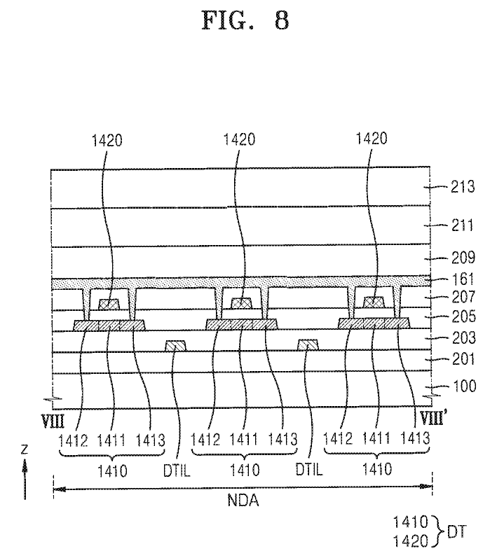

To improve monitoring accuracy, the dummy element region DER may include dummy elements configured to reflect various parameters affecting the gate line GL disposed in the display area DA, for example, resistance and capacitance. In an embodiment, the dummy elements may include a dummy transistor disposed in the non-display area NDA and electrically connected to the dummy gate line DGL (FIGS. 5 and 6). A specific structure of the dummy element region DER will be described below with reference to FIGS. 7 and 8.

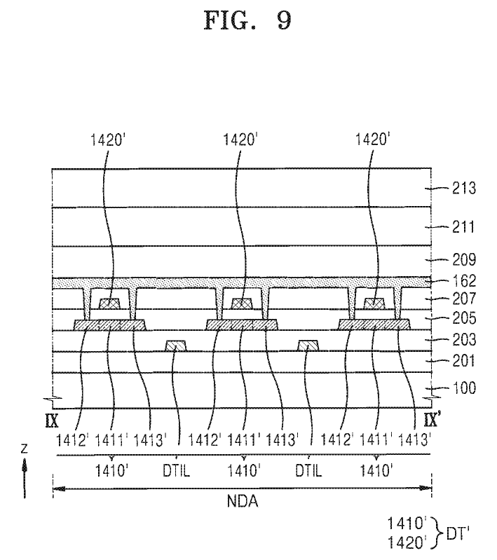

FIG. 7 is a plan view of a portion of the dummy element region DER according to an embodiment, FIG. 8 is a cross-sectional view taken along line VIII-VIII' of FIG. 7, and FIG. 9 is a cross-sectional view taken along line IX-IX' of FIG. 7.

In an embodiment, as shown in FIG. 7, the dummy gate lines DGL (FIG. 6) passing across the dummy element region DER may include first to fifth dummy gate lines DGL1, DGL2, DGL3, DGL4, and DGL5. The first to fifth dummy gate lines DGL1, DGL2, DGL3, DGL4, and DGL5 may extend in the first direction (e.g., the x direction) in the non-display area NDA.

In an embodiment, the first dummy gate line DGL1 is a dummy scan line, and the dummy driver 1120 (FIG. 6) may output, to the first dummy gate line DGL1, a signal (e.g., a scan signal) corresponding to the scan line GWL (FIG. 3) described with reference to FIG. 3. The second dummy gate line DGL2 is a dummy initialization gate line, and the dummy driver 1120 (FIG. 6) may output, to the second dummy gate line DGL2, a signal (e.g., an initialization signal) corresponding to the initialization gate line GIL (FIG. 3) described with reference to FIG. 3.

The third dummy gate line DGL3 is a dummy reference gate line, and the dummy driver 1120 (FIG. 6) may output, to the third dummy gate line DGL3, a signal (e.g., a reference signal) corresponding to the reference gate line GRL (FIG. 3) described with reference to FIG. 3. The fourth dummy gate line DGL4 is a dummy first emission control line, and the dummy driver 1120 (FIG. 6) may output, to the fourth dummy gate line DGL4, a signal (e.g., a first emission control signal) corresponding to the first emission control line EML (FIG. 3) described with reference to FIG. 3. The fifth dummy gate line DGL5 is a dummy second emission control line, and the dummy driver 1120 (FIG. 6) may output, to the fifth dummy gate line DGL5, a signal (e.g., a second emission control signal) corresponding to the second emission control line EMBL (FIG. 3) described with reference to FIG. 3.

Voltage lines having the same voltage level as that of a voltage line extending across the display area DA (FIG. 2) may be disposed in the non-display area NDA. In an embodiment, as shown in FIG. 7, the voltage lines may include first to sixth voltage lines 161, 162, 163, 164, 165, and 166 extending in the first direction (e.g., the x direction) in the non-display area NDA. The first to sixth voltage lines 161, 162, 163, 164, 165, and 166 may have a voltage level of a constant voltage, that is, each of the first to sixth voltage lines 161, 162, 163, 164, 165, and 166 transmits a voltage having a constant voltage level.

In an embodiment, the first voltage line 161 may have a voltage level of the common voltage ELVSS (FIG. 3), and the second voltage line 162 may have the same voltage level as the reference voltage Vref (FIG. 3). One of the third to fifth voltage lines 163, 164, and 165 may have the same voltage level as the initialization voltage Vaint (r) provided to the pixel circuit electrically connected to a first light-emitting diode (e.g., a red light-emitting diode) disposed in the display area DA (FIG. 2). Another of the third to fifth voltage lines 163, 164, and 165 may have the same voltage level as the initialization voltage Vaint (g) provided to the pixel circuit electrically connected to a second light-emitting diode (e.g., a green light-emitting diode) disposed in the display area DA (FIG. 2). The remaining one of the third to fifth voltage lines 163, 164, and 165 may have the same voltage level as the initialization voltage Vaint (b) provided to the pixel circuit electrically connected to a third light-emitting diode (e.g., a blue light-emitting diode) disposed in the display area DA (FIG. 2). The sixth voltage line 166 may have the same voltage level as the driving voltage ELVDD (FIG. 3).

In an embodiment, the first dummy gate line DGL1 may be electrically connected to a dummy transistor DT. As shown in FIGS. 7 and 8, the first dummy gate line DGL1 may be electrically connected to a plurality of dummy transistors DT apart from each other. The dummy transistor DT may include a dummy semiconductor layer 1410 and a dummy gate electrode 1420 overlapping a portion of the dummy semiconductor layer 1410. Referring to FIGS. 6 and 7, the dummy gate electrode 1420 of the dummy transistor DT may be electrically connected to the dummy driver 1120 through the dummy connection line DIL and the first dummy gate line DGL1.

The dummy semiconductor layer 1410 may be disposed in (or directly on) a same layer as the semiconductor layer of the switching transistor disposed in the display area DA (FIG. 4) and may include a same material as the semiconductor layer of the switching transistor. In an embodiment, for example, the dummy semiconductor layer 1410 may be disposed in (or directly on) a same layer as the semiconductor layer of the second transistor T2 (FIG. 4) disposed in the display area DA (FIG. 4) and may include a same material as the semiconductor layer of the second transistor T2, for example, an oxide semiconductor. In the disclosure, when two layers are disposed in a same layer, the two layers may be defined by patterned portions of a same material layer (or a same film) formed through a same process.

As shown in FIG. 8, the dummy semiconductor layer 1410 may be disposed on the second insulating layer 203 and may include a channel region 1411 overlapping the dummy gate electrode 1420, and first and second conductive regions 1412 and 1413 respectively disposed on two opposite sides of the channel region 1411. The channel region 1411 is a region having a relatively high resistance and may be referred to as a high resistance region, and the first and second conductive regions 1412 and 1413 are regions having a relatively low resistance and may be respectively referred to as first and second low resistance regions.

In an embodiment, the dummy gate electrode 1420 may be integrally connected to (or integrally formed with) the first dummy gate line DGL1 as a single unitary indivisible part, as shown in FIG. 7. In an embodiment, example, the dummy gate electrode 1420 may extend in the second direction (e.g., the y direction) from the first dummy gate line DGL1 extending in the first direction (e.g., the x direction). As shown in FIG. 8, the dummy gate electrode 1420 may be disposed on the third insulating layer 205 and may include the same material as the gate electrodes G1 and G2 of the first and second transistors T1 and T2 disposed in the display area DA (FIG. 4).

The dummy transistor DT may overlap a voltage line disposed thereon, for example, the first voltage line 161. In an embodiment, example, as shown in FIG. 7, an entire portion (i.e., the entirety) of the dummy semiconductor layer 1410 may overlap the first voltage line 161 in the third direction or the z direction. Referring to FIGS. 7 and 8, an entire portion of each of the channel region 1411, the first and second conductive regions 1412 and 1413 of the dummy semiconductor layer 1410 may overlap the first voltage line 161 in the third direction or the z direction.

The dummy transistor DT does not have a function (e.g., a switching function) of a transistor, and the dummy semiconductor layer 1410 may be electrically connected to a voltage line, for example, the first voltage line 161 on the dummy transistor DT. As shown in FIG. 8, the first voltage line 161 may be electrically connected to the first and second conductive regions 1412 and 1413. In an embodiment, example, a portion of the first voltage line 161 may be in direct contact with the first conductive region 1412 through a contact hole defined (or extending) through the third insulating layer 205 and the fourth insulating layer 207, and another portion of the first voltage line 161 may be in direct contact with the second conductive region 1413 through a contact hole defined (or extending) through the third insulating layer 205 and the fourth insulating layer 207.

A capacitance may be caused between the dummy gate electrode 1420 of the dummy transistor DT and the first voltage line 161, and a capacitance may be caused between the dummy semiconductor layer 1410 and the dummy gate electrode 1420. A signal transmitted through the first dummy gate line DGL1 electrically connected to the dummy transistor DT may be affected by not only a resistance of the first dummy gate line DGL1 but also the capacitances. The parameters (e.g., a resistance and a capacitance) affecting the first dummy gate line DGL1 are substantially equal to parameters (e.g., a resistance and a capacitance) affecting the gate line GL (FIG. 6), for example, the scan line GWL (FIG. 3) disposed in the display area DA, and may improve an accuracy of monitoring of the gate driver 1110 using the dummy driver 1120, for example, a monitoring performance of an output level of the scan line GWL (FIG. 3) as described with reference to FIG. 6.

In an embodiment, the second dummy gate line DGL2 may be electrically connected to a dummy transistor DT'. As shown in FIGS. 7 and 9, the second dummy gate line DGL2 may be electrically connected to a plurality of dummy transistors DT' apart from each other. The dummy transistor DT' may include a dummy semiconductor layer 1410' and a dummy gate electrode 1420' overlapping a portion of the dummy semiconductor layer 1410'. Referring to FIGS. 6 and 7, the dummy gate electrode 1420' of the dummy transistor DT' may be electrically connected to the dummy driver 1120 through the dummy connection line DIL and the second dummy gate line DGL2. The structures of the dummy semiconductor layer 1410' and the dummy gate electrode 1420' of the dummy transistor DT' shown in FIGS. 7 and 9, may be substantially the same as the structures of the dummy semiconductor layer 1410 and the dummy gate electrode 1420 of the dummy transistor DT described with reference to FIGS. 7 and 8.

The dummy semiconductor layer 1410' may be disposed in (or directly on) the same layer as the semiconductor layer of the switching transistor disposed in the display area DA (FIG. 4) and may include the same material as that of the semiconductor layer of the switching transistor. In an embodiment, for example, the dummy semiconductor layer 1410' may be disposed in (or directly on) the same layer as the semiconductor layer of the fourth transistor T4 (FIG. 3) disposed in the display area and may include the same material, for example, an oxide semiconductor as that of the semiconductor layer of the fourth transistor T4.

In an embodiment, as shown in FIG. 9, the dummy semiconductor layer 1410' may be disposed on the second insulating layer 203 and may include a channel region 1411' overlapping the dummy gate electrode 1420', and first and second conductive regions 1412' and 1413' respectively disposed on two opposite sides of the channel region 1411'. The channel region 1411' is a region having a relatively high resistance and may be referred to as a high resistance region, and the first and second conductive regions 1412' and 1413' are regions having a relatively low resistance and may be respectively referred to as first and second low resistance regions.

In an embodiment, the dummy gate electrode 1420' may be integrally connected to the second dummy gate line DGL2 as a single unitary indivisible part, as shown in FIG. 7. In an embodiment, for example, the dummy gate electrode 1420' may extend in the second direction (e.g., a -y direction) crossing the first direction (e.g., the x direction) from the second dummy gate line DGL2 extending in the first direction (e.g., the x direction). As shown in FIG. 9, the dummy gate electrode 1420' may be disposed on the third insulating layer 205 and may include the same material as the gate electrode of the fourth transistor T4 (FIG. 3) and/or the gate electrodes of the first and second transistors T1 and T2 disposed in the display area DA.

The dummy transistor DT' may overlap a voltage line disposed thereon, for example, the second voltage line 162 in the third direction or the z direction. In an embodiment, for example, as shown in FIG. 7, an entire portion of the dummy semiconductor layer 1410' may overlap the second voltage line 162, that is, the entirety of the dummy semiconductor layer 1410' may overlap the second voltage line 162 in the third direction or the z direction. Referring to FIGS. 7 and 9, an entire portion of each of the channel region 1411', the first and second conductive regions 1412' and 1413' of the dummy semiconductor layer 1410' may overlap the second voltage line 162 in the third direction or the z direction.

The dummy transistor DT' does not have a function (e.g., a switching function) of a transistor, and the dummy semiconductor layer 1410' may be electrically connected to a voltage line, for example, the second voltage line 162 on the dummy transistor DT'. As shown in FIG. 9, the second voltage line 162 may be electrically connected to the first and second conductive regions 1412' and 1413'. In an embodiment, for example, a portion of the second voltage line 162 may be in direct contact with the first conductive region 1412' through a contact hole defined (or extending) through the third insulating layer 205 and the fourth insulating layer 207, and another portion of the first voltage line 161 may be in direct contact with the second conductive region 1413' through a contact hole defined (or extending) through the third insulating layer 205 and the fourth insulating layer 207.

A capacitance may be caused between the dummy gate electrode 1420' of the dummy transistor DT' and the second voltage line 162, and a capacitance may be caused between the dummy semiconductor layer 1410' and the dummy gate electrode 1420'. A signal transmitted through the second dummy gate line DGL2 electrically connected to the dummy transistor DT' may be affected by not only a resistance of the second dummy gate line DGL2 but also the capacitances, and the parameters (e.g., a resistance and a capacitance) affecting the second dummy gate line DGL2 are substantially equal to parameters (e.g., a resistance and a capacitance) affecting the gate line GL (FIG. 6), for example, the initialization gate line GIL (FIG. 3) disposed in the display area DA, and may improve an accuracy of monitoring of the gate driver 1110 using the dummy driver 1120, for example, a monitoring performance of an output level of the initialization gate line GIL as described with reference to FIG. 6.

In an embodiment, as shown in FIG. 7, dummy transistors may not be electrically and respectively connected to the third and fifth dummy gate lines DGL3, DGL4, and DGL5. The third to fifth dummy gate lines DGL3, DGL4, and DGL5 may extend in the first direction (e.g., the x direction) and overlap the voltage lines, for example, the third and fourth voltage lines 163 and 164 disposed thereon. In this case, because there is only a capacitance component between the third dummy gate line DGL3 and the third voltage line 163, even though an output of a dummy gate signal of the third dummy gate line DGL3 is measured, it may be difficult to accurately monitor the reference gate line GRL (FIG. 3) providing a gate signal corresponding to the third dummy gate line DGL3. In other words, FIG. 7 shows an embodiment in which the dummy transistors DT and DT' are electrically connected to the first and second dummy gate lines DGL1 and DGL2 to monitor an output level of the scan line GWL (FIG. 3) and the initialization gate line GIL (FIG. 3) that provides gate signals respectively corresponding to the first and second dummy gate lines DGL1 and DGL2, and not to monitor the reference gate line GRL (FIG. 3), the first emission control line EML, and the second emission control line EMBL, which are different gate lines. However, the present disclosure is not limited thereto. In another embodiment, at least one selected from the third to fifth dummy gate lines DGL3, DGL4, and DGL5 may be electrically connected to additional dummy transistors having the same structure as that of the dummy transistors DT and DT' described with reference to FIGS. 7 to 9. The reference gate line GRL, the first emission control line EML, and the second emission control line EMBL providing gate signals respectively corresponding to the third to fifth dummy gate lines DGL3, DGL4, and DGL5 may be monitored by checking output levels of the third to fifth dummy gate lines DGL3, DGL4, and DGL5 electrically connected to the additional dummy transistors.

In an embodiment, as described above with reference to FIGS. 7 to 9, the dummy semiconductor layers 1410 and 1410' of the dummy transistors DT and DT' may be respectively and electrically connected to the first voltage line 161 having a voltage level of the common voltage, and the second voltage line 162 having a voltage level of the reference voltage, but the present disclosure is not limited thereto. The dummy semiconductor layers 1410 and 1410' of the dummy transistors DT and DT' may be electrically connected to the voltage line (e.g., one of the third to fifth voltage lines 163, 164, and 165) having a voltage level of the initialization voltage, or be electrically connected to the sixth voltage line 166 having a voltage level of the driving voltage.

Referring to FIGS. 7 to 9, a data connection line DTIL extending in the second direction (e.g., the y direction) to cross the first to sixth voltage lines 161, 162, 163, 164, 165, and 166 are disposed in the non-display area NDA. The data connection line DTIL may electrically connect the data driver circuitry 120 described with reference to FIG. 2 and the data line DL extending across the display area DA to each other. In an embodiment, as shown in FIGS. 8 and 9, the data connection line DTIL may be disposed between the first insulating layer 201 and the second insulating layer 203.

According to an embodiment of the present disclosure having the above construction, a display module capable of improving monitoring performance of a gate driver to display high-quality images, and an electronic apparatus including the display module may be implemented. However, the scope of the present disclosure is not limited by this effect.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display module comprising:
a light-emitting diode disposed in a display area;
a pixel circuit disposed in the display area and electrically connected to the light-emitting diode, wherein the pixel circuit includes a driving transistor and a switching transistor, the driving transistor includes a driving semiconductor layer and a driving gate electrode, and the switching transistor includes a switching semiconductor layer and a switching gate electrode;
a gate driver disposed in a non-display area adjacent to the display area and electrically connected to the switching transistor of the pixel circuit;
a dummy transistor disposed in the non-display area and including a dummy semiconductor layer and a dummy gate electrode overlapping a portion of the dummy semiconductor layer in a plan view;
a dummy driver disposed in the non-display area and electrically connected to the dummy gate electrode of the dummy transistor; and
a voltage line disposed on the dummy transistor in the non-display area and electrically connected to the dummy semiconductor layer of the dummy transistor.

2. The display module of claim 1, wherein the switching semiconductor layer and the dummy semiconductor layer include a same material.

3. The display module of claim 2, wherein each of the switching semiconductor layer and the dummy semiconductor layer includes an oxide semiconductor.

4. The display module of claim 1, wherein a material of the dummy gate electrode is the same as a material of the switching gate electrode.

5. The display module of claim 1, wherein a voltage transmitted through the voltage line has a constant voltage level.

6. The display module of claim 1, wherein the dummy semiconductor layer of the dummy transistor includes a high resistance region, and a first low resistance region and a second low resistance region respectively disposed on two opposite sides of the high resistance region,
the dummy gate electrode of the dummy transistor overlaps the high resistance region in the plan view, and
an entire portion of each of the high resistance region, the first low resistance region, and the second low resistance region of the dummy semiconductor layer overlaps the voltage line in the plan view.

7. The display module of claim 1, further comprising:
a dummy gate line extending in a same direction as the voltage line in the non-display area and electrically connected to the dummy driver,
wherein the dummy gate electrode is integrally connected to the dummy gate line as a single unitary indivisible part.

8. A display module comprising:
a gate line extending in a first direction in a display area;
a pixel circuit disposed in the display area and including a switching transistor and a driving transistor, wherein the switching transistor is electrically connected to the gate line, and the driving transistor is electrically connected to the switching transistor;
a light-emitting diode electrically connected to the pixel circuit and disposed in the display area;
a gate driver disposed in a non-display area adjacent to the display area and electrically connected to the gate line;
a dummy driver disposed in the non-display area;
a dummy gate line disposed in the non-display area and electrically connected to the dummy driver;
a dummy transistor disposed in the non-display area and including a dummy semiconductor layer and a dummy gate electrode, wherein the dummy gate electrode overlaps a portion of the dummy semiconductor layer in a plan view and is electrically connected to the dummy gate line; and
a voltage line disposed on the dummy transistor in the non-display area and electrically connected to the dummy semiconductor layer of the dummy transistor.

9. The display module of claim 8, wherein the dummy semiconductor layer includes a same material as a material of a switching semiconductor layer of the switching transistor.

10. The display module of claim 8, wherein a material of the dummy gate electrode is the same as a material of a gate electrode of the switching transistor.

11. The display module of claim 8, wherein a voltage transmitted through the voltage line has a constant voltage level.

12. The display module of claim 8, wherein the dummy semiconductor layer of the dummy transistor includes a high resistance region, and a first low resistance region and a second low resistance region respectively disposed on two opposite sides of the high resistance region,
the dummy gate electrode of the dummy transistor overlaps the high resistance region in the plan view, and
an entire portion of the dummy semiconductor layer overlaps the voltage line in the plan view.

13. The display module of claim 8, wherein the dummy gate line is integrally connected to the dummy gate electrode as a single unitary indivisible part.

14. An electronic apparatus comprising:
a display module; and
a power module which supplies power to the display module,
wherein the display module comprises:
a light-emitting diode disposed in a display area;
a pixel circuit disposed in the display area and electrically connected to the light-emitting diode, wherein the pixel circuit includes a driving transistor and a switching transistor, the driving transistor includes a driving semiconductor layer and a driving gate electrode, and the switching transistor includes a switching semiconductor layer and a switching gate electrode;
a gate driver disposed in a non-display area adjacent to the display area and electrically connected to the switching transistor of the pixel circuit;
a dummy transistor disposed in the non-display area and including a dummy semiconductor layer and a dummy gate electrode overlapping a portion of the dummy semiconductor layer in a plan view;
a dummy driver disposed in the non-display area and electrically connected to the dummy gate electrode of the dummy transistor; and
a voltage line disposed on the dummy transistor in the non-display area and electrically connected to the dummy semiconductor layer of the dummy transistor.

15. The electronic apparatus of claim 14, wherein the switching semiconductor layer and the dummy semiconductor layer include a same material.

16. The electronic apparatus of claim 14, wherein each of the switching semiconductor layer and the dummy semiconductor layer includes an oxide semiconductor.

17. The electronic apparatus of claim 14, wherein a material of the dummy gate electrode is the same as a material of the switching gate electrode.

18. The electronic apparatus of claim 14, wherein a voltage transmitted through the voltage line has a constant voltage level.

19. The electronic apparatus of claim 14, wherein the dummy semiconductor layer of the dummy transistor includes a high resistance region, and a first low resistance region and a second low resistance region respectively disposed on two opposite sides of the high resistance region,
the dummy gate electrode of the dummy transistor overlaps the high resistance region in the plan view, and
an entire portion of each of the high resistance region, the first low resistance region, and the second low resistance region of the dummy semiconductor layer overlaps the voltage line in the plan view.

20. The electronic apparatus of claim 14, wherein the display module further comprises: a dummy gate line extending in a same direction as the voltage line in the non-display area and electrically connected to the dummy driver,
wherein the dummy gate electrode is integrally connected to the dummy gate line as a single unitary indivisible part.
